(19) United States
(12) Patent Application Publication
(10) Pub. No.: US 2001/0006241 A1
(43) Pub. Date: Jul. 5, 2001

(54) Semicconductor device having a capacitor and method for the manufacture thereof

(76) Inventor: Bee-Lyong Yang, Ichon-shi (KR)

Correspondence Address: JACOBSON, PRICE, HOLMAN & STERN, PROFESSIONAL LIMITED LIABILITY COMPANY, 400 Seventh Street, N.W., Washington, DC, 20004, US

(21) Appl. No.: 09/739,372

(22) Filed: Dec. 19, 2000

(30) Foreign Application Priority Data
Dec. 30, 1999 (KR) 1999-65829

(51) Int. Cl. H01L 21/00; H01L 21/8242; H01L 27/108

(52) U.S. Cl. 257/310; 438/3; 438/253; 438/396

(57) ABSTRACT

A semiconductor device for use in a memory cell including an active matrix provided with a transistor and a first insulating layer formed around the transistor; a capacitor structure, formed on top of the first insulating layer, composed of a bottom electrode, a capacitor thin film placed on top of the bottom electrode and a top electrode formed on top of the capacitor thin film; a hydrogen barrier layer, formed on the capacitor structure, for protecting the capacitor structure from hydrogen diffusion; a second insulating layer formed on top of the transistor and the capacitor structure; and a metal interconnection formed on top of the second insulating layer to electrically connect the transistor to the capacitor structure.

### FIELD OF THE INVENTION

The present invention relates to a semiconductor device; and, more particularly, to a semiconductor device having a capacitor structure for use in a memory cell and a method for the manufacture thereof.

### DESCRIPTION OF THE PRIOR ART

As is well known, a dynamic random access memory (DRAM) with a memory cell comprised of a transistor and a capacitor has a higher degree of integration mainly by down-sizing through micronization. However, there is still a demand for downsizing the area of the memory cell.

To meet the demand, several methods have been proposed such as a trench type or a stack type capacitor, which is arranged three-dimensionally in a memory device to reduce the cell area available to the capacitor. However, the process of manufacturing a three-dimensionally arranged capacitor is a long and tedious one and consequently incurs high manufacturing costs. Therefore, there is a strong demand for a new memory device that can reduce the cell area while securing a requisite volume of information without requiring complex manufacturing steps.

DRAM devices employ a high dielectric material as a capacitor thin film such as barium strontium titanate (BST) and tantalum oxide (Ta₂O₅) to meet the demand. However, while DRAM is small, inexpensive, fast, and expends little power, DRAM is volatile and has to be refreshed many times each second.

In an attempt to solve the above problem of DRAM, there has been proposed a ferroelectric random access memory (FeRAM) where a capacitor thin film with ferroelectric properties such as strontium bismuth tantalate (SBT) and lead zirconate titanate (PZT) is used for a capacitor in place of a conventional silicon oxide film or a silicon nitride film. FeRAM has a non-volatile property due to remnant polarization of a ferroelectric material and it can operate at lower voltages.

In manufacturing a memory device such as DRAM and FeRAM, there is a step of forming a passivation layer on top of a metal interconnection layer, for protecting the semiconductor device from exposure to detrimental environmental factors such as moisture, particles or the like. The passivation layer is formed by using a method such as plasma enhanced chemical vapor deposition (PECVD) in hydrogen rich atmosphere. However, during the passivation process, the hydrogen gas generated by CVD process degrades the capacitor of the memory cell. That is, the hydrogen gas and ions penetrate to a top electrode and a side of the capacitor, reaching to the capacitor thin film and reacting with oxygen atoms constituting the ferroelectric material of the capacitor thin film.

These problems, therefore, tend to make it difficult to obtain the desired reproducibility, reliability and yield in fabricating the memory cell.

### SUMMARY OF THE INVENTION

It is, therefore, an object of the present invention to provide a semiconductor device incorporating therein a double hydrogen barrier layer provided with a titanium (Ti) layer and a tetra-ethyl-ortho-silicate (TEOS) oxide layer to protect a capacitor from hydrogen damage during formation of a passivation layer.

It is another object of the present invention to provide a method for manufacturing a semiconductor device incorporating the double hydrogen barrier layer therein to protect a capacitor from hydrogen damage during the formation of a passivation layer.

In accordance with one aspect of the present invention, there is provided a semiconductor device for use in a memory cell, including: an active matrix provided with a transistor and a first insulating layer formed around the transistor; a capacitor structure, formed on top of the first insulating layer, composed of a bottom electrode, a capacitor thin film placed on top of the bottom electrode and a top electrode formed on top of the capacitor thin film; a hydrogen barrier layer, formed on the capacitor structure, for protecting the capacitor structure from hydrogen diffusion; a second insulating layer formed on top of the transistor and the capacitor structure; and a metal interconnection formed on top of the second insulating layer to electrically connect the transistor to the capacitor structure.

In accordance with another aspect of the present invention, there is provided a method for manufacturing a semiconductor device for use in a memory cell, the method including the steps of: a) preparing an active matrix provided with a transistor and a first insulating layer formed around the transistor; b) forming a capacitor structure on top of the first insulating layer, with the capacitor structure including a capacitor thin film made of a ferroelectric material; c) forming a hydrogen barrier layer on top of the capacitor structure; d) forming a second insulating layer on top of the capacitor and transistor structure; and e) forming a metal interconnection layer and patterning it into a first predetermined configuration to electrically connect the transistor to the capacitor structure.

### BRIEF DESCRIPTION OF THE DRAWINGS

The above and other objects and features of the present invention will become apparent from the following description of the preferred embodiments given in conjunction with the accompanying drawings, in which:

FIG. 1 is a cross sectional view setting forth a semiconductor device in accordance with a preferred embodiment of the present invention; and

FIGS. 2A to 2F are schematic cross sectional views setting forth a method for the manufacture of the semiconductor memory device in accordance with the present invention;

### DETAILED DESCRIPTION OF THE PREFERRED EMBODIMENTS

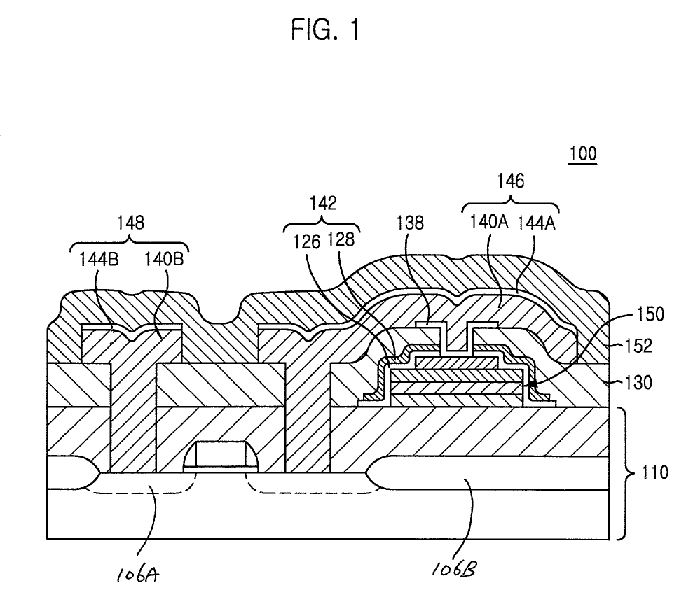

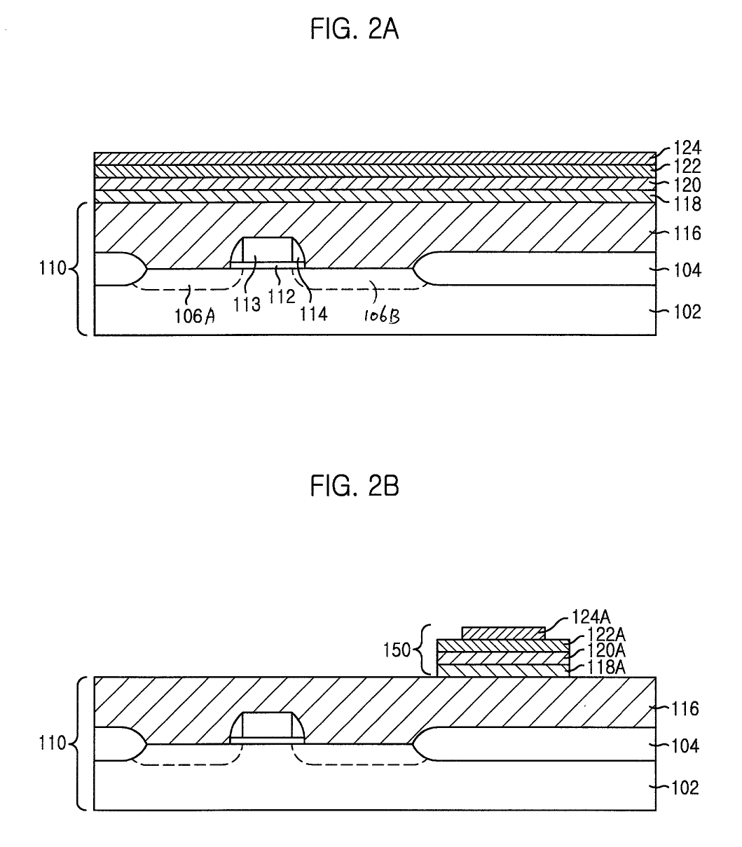

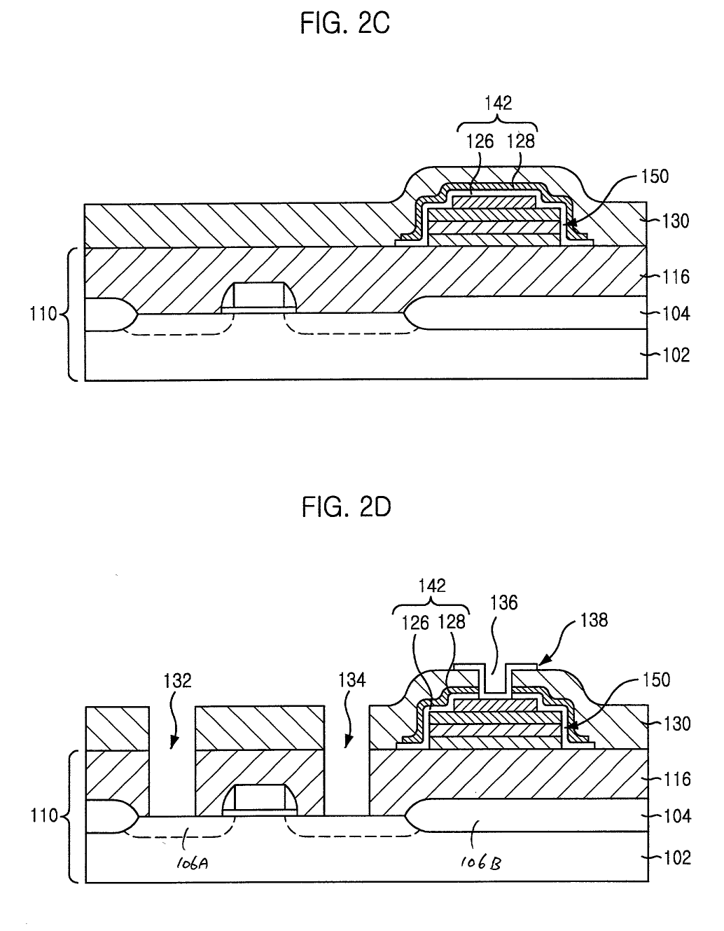

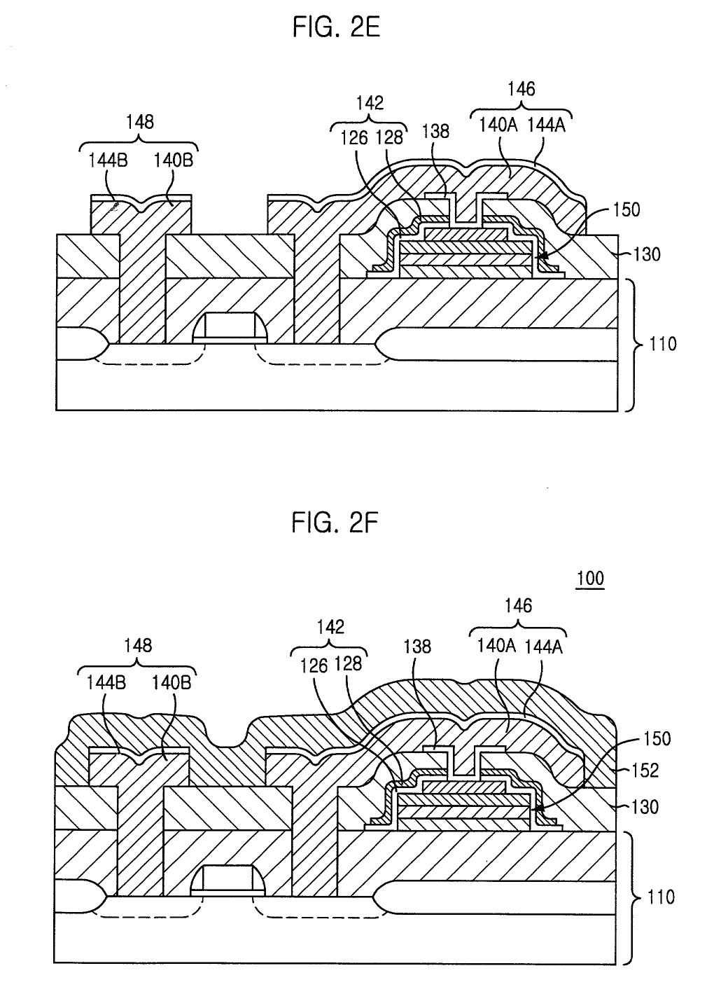

There are provided in FIG. 1 and FIGS. 2A to 2F cross sectional views of a semiconductor device 100 for use in a memory cell and cross sectional views setting forth a method for the manufacture thereof in accordance with a preferred embodiment of the present invention. It should be noted that like parts appearing in FIG. 1 and FIGS. 2A to 2F are represented by like reference numerals.

In FIG. 1, there is provided a cross sectional view of the inventive semiconductor device 100 including an active matrix 110, a second insulating layer 130, a double hydrogen barrier layer 142 provided with a tetra-ethyl-ortho-silicate (TEOS) oxide layer 126 and a Ti metal layer 128, a bit line 148 provided with a first metal layer 140B and a second metal layer 144B, a metal interconnection 146 provided with the first metal layer 140A and the second metal layer 144A, and a capacitor structure 150.

In addition, a passivation layer 152 made of a material selected from the group consisting of undoped silicate glass (USG), Si₃N₄ or combination thereof, is formed on top of the bit line 148, the metal interconnection 146 and the second insulating layer 130 by using a chemical vapor deposition (CVD) or a physical vapor deposition (PVD) for protecting the semiconductor device 100 from exposure to detrimental environmental substances.

In the semiconductor device 100, the bit line 148 is electrically connected to a diffusion region 106A and a top electrode of the capacitor structure 150 is electrically connected to another diffusion region 106B through the metal interconnection 146, wherein the bit line 148 and the metal interconnection 146 are electrically disconnected from each other. A bottom electrode of the capacitor structure 150 may be connected to a plate line (not shown) to apply a common constant potential thereto. In the preferred embodiment of the present invention, the first metal layer 140A, 140B is made of Ti, and the second metal layer 144A, 144B is made of a material selected from the group consisting of TiN, Al, TiW or the like.

Between the bottom and the top electrodes, there is a capacitor thin film made of a ferroelectric material such as SBT (SrBiTaOₓ), PZT (PbZrTiOₓ) or the like. Here, a double hydrogen barrier layer 142 provided with the TEOS oxide layer 126 and the Ti metal layer 128 plays an important role in preventing hydrogen diffusion into the capacitor structure 150 during a formation of the passivation layer 152, because the passivation process is carried out at a high temperature, i.e., 320° C. to 400° C., in hydrogen rich ambient.

FIGS. 2A to 2F are schematic cross sectional views setting forth the method for manufacture of a semiconductor memory device 100 in accordance with a preferred embodiment of the present invention.

The process for manufacturing the semiconductor device 100 begins with the preparation of an active matrix 110 including a semiconductor substrate 102, an isolation region 104, diffusion regions 106A, 106B, a gate oxide 112, a gate line 113, a spacer 114 and a first insulating layer 116, as shown in FIG. 2A. One of the diffusion regions serves as a source and the other diffusion region serves as a drain. The first insulating layer 116 is made of a material such as boron-phosphor-silicate glass (BPSG) or medium temperature oxide (MTO) or the like.

Thereafter, a buffer layer 118, e.g., made of Ti or TiOₓ, is formed with a thickness ranging from 50 nm to 250 nm on top of the first insulating layer 116. A first metal layer 120, a dielectric layer 122 and a second metal layer 124 are subsequently formed on top of the buffer layer 118, as shown in FIG. 2A. In the preferred embodiment, the dielectric layer 122 is made of a ferroelectric material such as strontium bismuth tantalate (SBT), lead zirconate titanate (PZT) or the like and formed with a thickness ranging from 50 nm to 250 nm by using a method such as a spin coating, a chemical vapor deposition (CVD) or the like. In addition, the first and the second metal layers 120, 124 are made of platinum (Pt), formed with a thickness of approximately 200 nm, in the preferred embodiment of the present invention.

After forming the layers 118, 120, 122, 124, the second metal layer 124 is patterned into a first predetermined configuration to obtain a top electrode 124A, as shown in FIG. 2B. The dielectric layer 122, the first metal layer 120 and the buffer layer 118 are patterned into a second predetermined configuration to obtain a bottom electrode structure, thereby forming a capacitor structure 150 having a buffer 118A, a bottom electrode 120A, a capacitor thin film 122A and a top electrode 124A. It is preferable that the bottom electrode 120A have a size different from that of the top electrode 124A in order to form a plate line (not shown) during the following processes.

In a next step as shown in FIG. 2C, a TEOS oxide layer 126 and a Ti metal layer 128 are formed on top of the capacitor structure 150, and then are patterned, thereby to obtain a double hydrogen barrier layer 142 provided with the TEOS oxide layer 126 and the Ti metal layer 128. Preferably, the Ti metal layer 128 is formed with a thickness of at least approximately 10 nm. Thereafter, a second insulating layer 130 is formed on the double hydrogen barrier layer 142 and the active matrix 110, with the second insulating layer 130 being formed with a thickness of approximately 100 nm and being made of BPSG or MTO.

In an ensuing step as shown in FIG. 2D, a first opening 132 and a second opening 134 are formed at positions over the diffusion regions 106A, 106B, respectively, through the second and the first insulating layers, 130, 116, respectively, by using a method such as photolithography and plasma etching, e.g., reactive ion etching (RIE). A third opening 136 is formed at a position over the capacitor structure 150 through the second insulating layer 130 and the double hydrogen barrier layer 142 by using a method such as photolithography and plasma etching. Here, a reference numeral 138 denotes a TiN layer formed on top electrode 124A through the third opening 136 for enhancing the adhesion of the top electrode 124A and a metal interconnection 146 which will be formed during a next step.

Thereafter, a first metal layer 140 is formed over the entire surface including the interiors of the openings 132, 134, 136 and then, a second metal layer 144 is formed on top of the first metal layer 140. The first and the second metal layers 140, 144 are patterned into a preset configuration to form a bit line 148 with a first metal layer 140B and a second metal layer 144B, and a metal interconnection 146 with a first metal layer 140A and a second metal layer 144A, as shown in FIG. 2E. In the preferred embodiment, the first metal layer 140 is made of a material selected from the group consisting of TiN, Al, TiW or the like.

Finally, a passivation layer 152 made of a material selected from a group consisting of undoped silicate glass (USG), Si₃N₄ or combination thereof, is formed on top of the metal interconnection 146, the bit line 148 and the second insulating layer 130 by using a method such as CVD or PVD to protect the semiconductor device 100 from exposure to detrimental environmental factors such as moisture, particles or the like, as shown in FIG. 2F.

By structuring the semiconductor device 100 of the present invention as aforementioned, it is possible to prevent the capacitor structure 150 from being damaged by hydrogen penetration thereinto. That is, by means of the formation of the Ti metal layer 140A of the metal interconnection 146 and the double hydrogen barrier layer 142, hydrogen damage is effectively avoided because diffusion velocities of hydrogen atoms are markedly decreased in the Ti metal.

While the present invention has been described with respect to the particular embodiments, it will be apparent to those skilled in the art that various changes and modifications may be made without departing from the scope of the invention as defined in the following claims.

What is claimed is:

1. A semiconductor device for use in a memory cell, comprising:
an active matrix provided with a transistor and a first insulating layer formed around the transistor;
a capacitor structure, formed on top of the first insulating layer, composed of a bottom electrode, a capacitor thin film placed on top of the bottom electrode and a top electrode formed on top of the capacitor thin film;
a hydrogen barrier layer, formed on the capacitor structure, for protecting the capacitor structure from a hydrogen diffusion;
a second insulating layer formed on top of the transistor and the capacitor structure; and
a metal interconnection formed on top of the second insulating layer to electrically connect the transistor to the capacitor structure.

2. The semiconductor device of claim 1, further comprising:
a titanium nitride (TiN) adhesion layer for connecting the metal interconnection and the top electrode, formed on top of the top electrode; and
a passivation layer formed on top of the metal interconnection by using a chemical vapor deposition (CVD) or a physical vapor deposition (PVD) in a hydrogen rich atmosphere.

3. The semiconductor device of claim 1, wherein the hydrogen barrier layer is made of a Ti metal layer and a tetra-ethyl-ortho-silicate (TEOS) oxide layer.

4. The semiconductor device of claim 3, wherein a thickness of the Ti metal layer is at least 10 nm.

5. The semiconductor device of claim 1, wherein the metal interconnection includes a Ti metal and another material selected from the group consisting of TiN, Al or TiW.

6. The semiconductor device of claim 1, wherein the capacitor thin film includes a ferroelectric material selected from the group consisting of SBT (SrBiTaOₓ) and PZT (PbZrTiOₓ).

7. The semiconductor device of claim 2, wherein the passivation layer includes a material selected from the group consisting of undoped silicate glass (USG) and Si₃N₄ and a combination thereof.

8. A method for manufacturing a semiconductor device for use in a memory cell, the method comprising the steps of:
a) preparing an active matrix provided with a transistor and a first insulating layer formed around the transistor;
b) forming a capacitor structure on top of the first insulating layer, wherein the capacitor structure includes a capacitor thin film made of a ferroelectric material;
c) forming a hydrogen barrier layer on top of the capacitor structure;
d) forming a second insulating layer on top of the capacitor and transistor structure; and
e) forming a metal interconnection layer and patterning said metal interconnection layer into a first predetermined configuration to electrically connect the transistor to the capacitor structure.

9. The method of claim 8, further comprising the steps of:
d-1) forming a TiN adhesion layer on top of a top electrode within said capacitor structure for connecting the metal interconnection layer and the top electrode;
d-2) forming a passivation layer on top of the metal interconnection layer by using CVD or PVD method in a hydrogen rich atmosphere.

10. The method of claim 8, wherein the hydrogen barrier layer is made of a Ti metal layer and a tetra-ethyl-ortho-silicate (TEOS) oxide layer.

11. The method of claim 10, wherein a thickness of the Ti metal layer is at least 10 nm.

12. The method of claim 8, wherein the metal interconnection layer is made of a Ti metal and another material selected from the group consisting of TiN, Al and TiW.

13. The method of claim 8, wherein the capacitor thin film is made of a ferroelectric material selected from the group consisting of SBT (SrBiTaOₓ) and PZT (PbZrTiOₓ).

14. The method of claim 9, wherein the passivation layer is made of a material selected from the group consisting of undoped silicate glass (USG), Si₃N₄ and a combination thereof.
